(19) United States
(12) Patent Application Publication
(10) Pub. No.: US 2022/0068619 A1
(43) Pub. Date: Mar. 3, 2022

(54) SYSTEMS AND METHODS FOR A MAGNETRON WITH A SEGMENTED TARGET CONFIGURATION

(71) Applicant: OEM Group, LLC, Gilbert, AZ (US)

(72) Inventors: Marc-Andre Lariviere, Mesa, AZ (US); Juan M. Rios Reyes, Exeter, CA (US); Nitin Choudhary, Mesa, AZ (US); Chao Li, Chandler, AZ (US); Brendan V. Trang, La Puente, CA (US); Christian K. Forgey, Round Rock, TX (US); Michael S. Correra, Staten Island, NY (US)

(73) Assignee: OEM Group, LLC, Gilbert, AZ (US)

(21) Appl. No.: 17/389,264

(22) Filed: Jul. 29, 2021

Related U.S. Application Data
(60) Provisional application No. 63/072,737, filed on Aug. 31, 2020.

(51) Int. Cl. H01J 37/34; C23C 14/35

(52) U.S. Cl. CPC H01J 37/345; C23C 14/352; C23C 14/351; H01J 37/3405

(57) ABSTRACT

The present invention provides a magnetron system comprising a baseplate assembly that defines a housing portion and a power feedthrough. A magnet assembly and a segmented target assembly are disposed within the housing portion. The segmented target assembly has an inner target segment having a plurality of target tiles. A plurality of electrical contacts are in electrical communication with the power feedthrough, wherein each electrical contact of the plurality of electrical contacts electrically contacts a respective target tile of the plurality of target tiles such that power is delivered from each electrical contact of the plurality of electrical contacts to each respective target tile of the plurality of target tiles.

### CROSS REFERENCES TO RELATED APPLICATIONS

This application claims priority from and is related to commonly owned U.S. Provisional Patent Application Ser. No. 63/072,737 filed Aug. 31, 2020, entitled: SYSTEMS AND METHODS FOR A MAGNETRON WITH A SEGMENTED TARGET CONFIGURATION, this Provisional Patent Application incorporated by reference herein.

### FIELD OF THE INVENTION

The present disclosure generally relates to physical vapor deposition; and in particular, to a system and associated method for modulating sputter rates for target materials using a magnetron with segmented targets.

### BACKGROUND OF THE INVENTION

Sputtering is often used for physical vapor deposition of materials onto arbitrary wafers. Sputtering occurs when microscopic molecules are eroded from a solid target surface after being bombarded with energized ions of plasma or gas. In wafer manufacturing, this process is used to deposit uniform microscopic films onto a wafer. Typically, eroded material from the target surface is deposited onto the wafer. For instance, to deposit an aluminum film onto a silicon wafer, the target surface would be aluminum.

In a magnetron, plasma is created by ionizing a non-reactive gas, typically Argon (Ar) by low-pressure separation of positively charged ions from negatively charged electrons. The positively charged ions are accelerated towards a negatively charged electrode, i.e. the target surface and strike the negatively charged electrode with enough force to dislodge and eject molecules from the target surface. Such molecules then condense onto the wafer which is placed in proximity to a magnetron sputtering cathode. To deposit compound materials onto wafer surface, a reactive gas is introduced into the Ar gas plasma. For example, nitrogen gas is used with Argon to deposit AIN films from an Al target.

Scandium (Sc) doped aluminum nitride (AIN) films are gaining significant interest from the industry and scientific communities for next generation electroacoustic and piezo-MEMS devices, owing to significant enhancement in its piezoelectric properties compared to pristine AIN. In particular, scandium-doped aluminum nitride (AlScN) opens avenues for CMOS-compatible next-generation memory devices; however, the careful deposition of a precise ratio of scandium to aluminum is a challenge and is not easily achieved with current sputtering devices.

Nothing in the prior art provides the benefits attendant with the present invention.

Therefore, it is an object of the present invention to provide an improvement which overcomes the inadequacies of the prior art devices and which is a significant contribution to the advancement of using a magnetron system.

Another object of the present invention is to provide a magnetron system, comprising a baseplate assembly defining a housing portion and a power feedthrough; a segmented target assembly having an inner target segment disposed within the housing portion, the inner target segment having a plurality of target tiles; a plurality of electrical contacts in electrical communication with the power feedthrough, wherein each electrical contact of the plurality of electrical contacts electrically contacts a respective target tile of the plurality of target tiles such that power is delivered from each electrical contact of the plurality of electrical contacts to each respective target tile of the plurality of target tiles; and a magnet assembly disposed within the housing portion.

Yet another object of the present invention is to provide a magnetron system, comprising a baseplate assembly defining a housing portion and a power feedthrough; a segmented target assembly disposed within the housing portion, the segmented target assembly having an inner target segment having a plurality of target tiles and an outer target segment having a plurality of target tiles, wherein a first subset of the plurality of target tiles are comprised of a first material and wherein a second subset of the plurality of target tiles are comprised of a second material, wherein the plurality of target tiles are arranged in an alternating order such that a target tile of the plurality of target tiles comprising the first material is juxtapositioned between two target tiles of the plurality of target tiles comprising the second material, and a target tile of the plurality of target tiles comprising the second material is juxtapositioned between two target tiles of the plurality of target tiles comprising the first material; and a magnet assembly disposed within the housing portion.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

The invention described herein provides greater control of the uniformity of the deposition of a compound material onto a substrate through the use of a segmented target assembly in a physical vapor deposition system.

A feature of the present invention is to provide a magnetron system comprising a baseplate assembly that defines a housing portion and a power feedthrough. A magnet assembly and a segmented target assembly are disposed within the housing portion. The segmented target assembly has an inner target segment having a plurality of target tiles. A plurality of electrical contacts are in electrical communication with the power feedthrough, wherein each electrical contact of the plurality of electrical contacts electrically contacts a respective target tile of the plurality of target tiles such that power is delivered from each electrical contact of the plurality of electrical contacts to each respective target tile of the plurality of target tiles. The segmented target assembly can further comprise an outer target segment wherein the outer target segment surrounds the inner target segment. The magnet assembly can further comprise an outer magnet assembly comprising a first grouping of the plurality of magnet pairs and an inner magnet assembly comprising a second grouping of the plurality of magnet pairs wherein the outer magnet assembly surrounds the inner magnet assembly. The magnetron system can further comprise a water jacket assembly wherein the water jacket assembly comprises an outer water jacket disposed within an outer magnet assembly of the magnet assembly and an inner water jacket disposed within an inner magnet assembly of the magnet assembly. The inner target segment can be in a concentric configuration, the outer target segment can be in a concentric configuration, the inner magnet assembly can be in a concentric configuration, the outer magnet assembly can be in a concentric configuration, the inner water jacket can be in a concentric configuration, and the outer water jacket can be in a concentric configuration. The baseplate assembly can further comprise a gas tower in fluid flow communication with a gas assembly, the gas tower being operable for introducing a gas into the system. Each magnet pair can further comprise a vertical magnet and a horizontal magnet, each vertical magnet being aligned with an axis Z and each horizontal magnet being aligned perpendicular to each vertical magnet. The system can further comprise a first subset of the plurality of target tiles having a first material and a second subset of the plurality of target tiles having a second material. The plurality of target tiles can be arranged in an alternating order such that a target tile of the plurality of target tiles having the first material is juxtapositioned between two target tiles of the plurality of target tiles having the second material, and a target tile of the plurality of target tiles having the second material is juxtapositioned between two target tiles of the plurality of target tiles having the first material. The first material can be aluminum. The second material can be scandium. The plurality of target tiles can be electrically isolated from one another. The outer target segment and the inner target segment can be electrically isolated from one another by an annular target shield. The outer target segment and the inner target segment can be electrically isolated from one another by a plurality of spacers. The magnet assembly can be positioned inferior to the segmented target assembly, the magnet assembly can have a plurality of magnet pairs, wherein each magnet pair can be positioned annularly around a central axis Z. The magnet assembly can further comprise a plurality of pole pieces wherein each magnet pair contacts at least two pole pieces of the plurality of pole pieces. A diameter of the inner magnet assembly can be less than a diameter of the outer magnet assembly.

Another feature of the present invention is to provide a magnetron system comprising a baseplate assembly that defines a housing portion and a power feedthrough. A magnet assembly and a segmented target assembly are disposed within the housing portion. The segmented target assembly has an inner target segment having a plurality of target tiles and an outer target segment having a plurality of target tiles. Each target tile of the plurality of target tiles can be electrically isolated from one another. A first subset of the plurality of target tiles having a first material and a second subset of the plurality of target tiles having a second material wherein the plurality of target tiles are arranged in an alternating order such that a target tile of the plurality of target tiles having the first material is juxtapositioned between two target tiles of the plurality of target tiles having the second material, and a target tile of the plurality of target tiles having the second material is juxtapositioned between two target tiles of the plurality of target tiles having the first material. The first material can be aluminum. The second material can be scandium. A plurality of electrical contacts can be in electrical communication with the power feedthrough, wherein each electrical contact of the plurality of electrical contacts can electrically contact a respective target tile of the plurality of target tiles such that power is delivered from each electrical contact of the plurality of electrical contacts to each respective target tile of the plurality of target tiles. The segmented target assembly can further comprise the outer target segment surrounding the inner target segment. The magnet assembly can further comprise an outer magnet assembly comprising a first grouping of the plurality of magnet pairs and an inner magnet assembly comprising a second grouping of the plurality of magnet pairs wherein the outer magnet assembly surrounds the inner magnet assembly.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 is a perspective view of a magnetron having a segmented target assembly;

FIG. 2 is an exploded view of the magnetron of FIG. 1;

FIG. 3 is an exploded view of the segmented target assembly of the magnetron of FIG. 1;

FIG. 4 is a side view of an internal assembly of the magnetron of FIG. 1 featuring a water jacket assembly, a magnet assembly, and a plurality of electrical contacts;

FIG. 5 is an exploded view of the internal assembly of FIG. 4;

FIGS. 6A and 6B are perspective views respectively showing an outer magnet assembly and an inner magnet assembly of a magnet assembly of the internal assembly of FIG. 4 showing a plurality of electrical contacts;

FIG. 7 is a side view of the magnet assembly showing a plurality of electrical contacts of the power assembly;

FIG. 8 is a cross sectional view of the magnet assembly taken along line 8-8 of FIG. 7;

FIG. 9 is a cross-sectional view of the internal assembly of the magnetron featuring a channel of the water jacket assembly and an electrical contact of the plurality of electrical contacts taken along line 9-9 of FIG. 4;

FIG. 10 is a top view of the water jacket assembly and the plurality of electrical contacts of FIG. 4;

FIG. 11 is a perspective view of a baseplate assembly of the magnetron of FIG. 1; and

FIG. 12 is an exploded view of the baseplate assembly of FIG. 11.

Corresponding reference characters indicate corresponding elements among the view of the drawings. The headings used in the figures do not limit the scope of the claims.

### DETAILED DESCRIPTION OF THE INVENTION

Various embodiments of a magnetron featuring a segmented target assembly for producing uniform films in a selected single or multi-material concentration on an electronic wafer are disclosed. In some embodiments, the segmented target assembly includes a plurality of target segments. Note that the descriptions that follow are for a “sputter up” system configuration where the wafer is typically held above the sputter source. The invention can be practiced in other configurations (e.g., where the target is above the wafer). Surfaces on the side of the wafer facing the sputter target will be subject to deposted film from the sputter source.

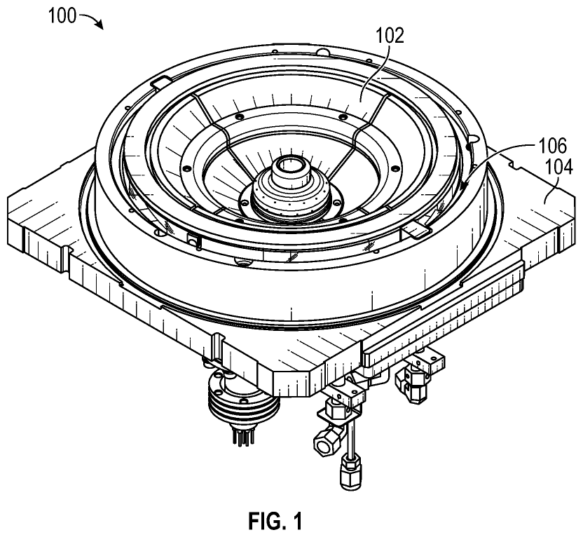

In one particular embodiment, one or more target tiles of the segmented target assembly may include scandium (Sc) and one or more target tiles of the segmented target assembly may include aluminum (Al). To produce a uniform aluminum scandium nitride (AlScN) film onto a wafer, the wafer is held above the segmented target assembly and a negative charge is applied to each target segment by one of a plurality of electrical contacts. The amount of negative charge applied to each target segment directly affects its sputtering rate, thus the magnetron system modulates an amount of charge applied to each target segment of the segmented target assembly by the plurality of electrical contacts, thereby individually modulating a sputtering rate of each segment. The power in the form of charge applied to each target segment can be increased or decreased in order to maintain uniformity of material deposition on the wafer surface as the target erodes over time. The power in the form of charge applied to each target segement can also be used to maintain a proper doping concentration between elements (e.g., Al and Sc film content in the case of depositing AlScN films). Referring to the drawings, embodiments of a magnetron featuring a segmented target assembly are illustrated and generally indicated as 100 in FIGS. 1-12.

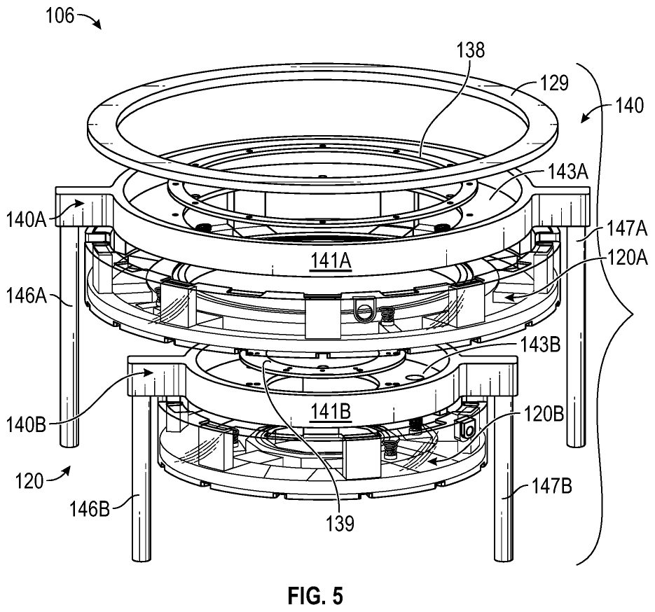

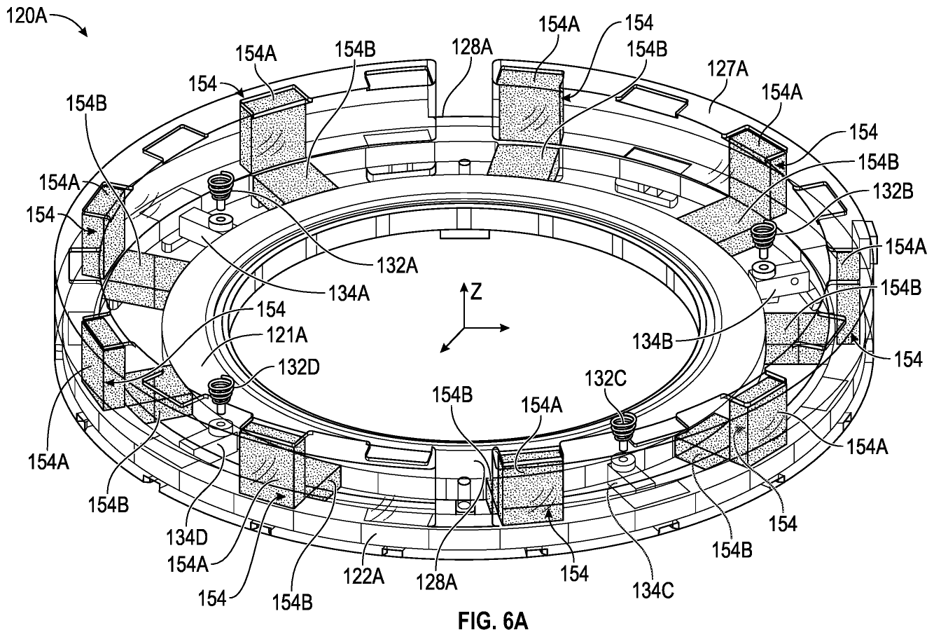

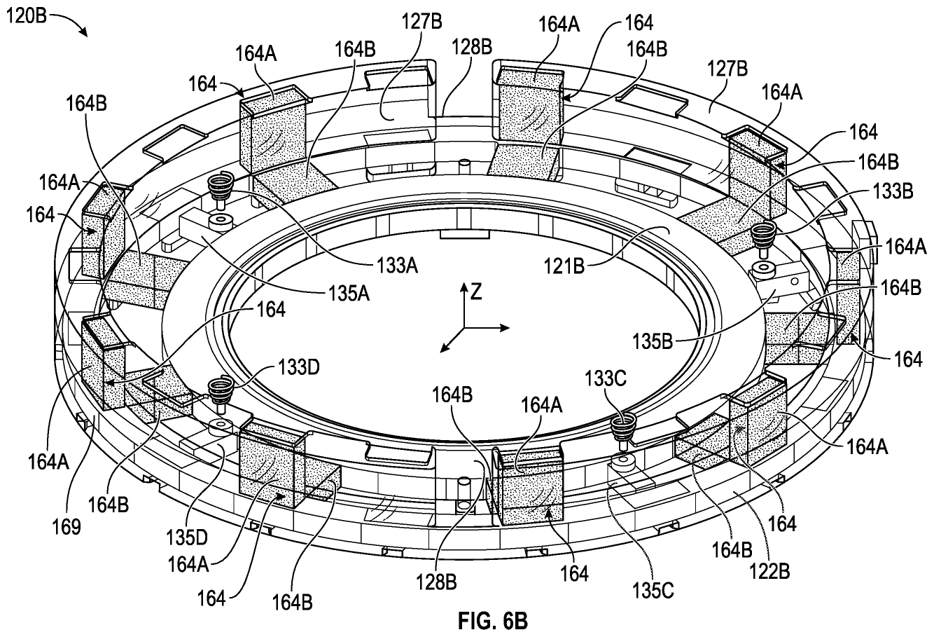

Referring to FIGS. 1-3, a magnetron system 100 featuring a segmented target assembly 102 for improved physical vapor deposition onto a wafer surface of a wafer (not shown) is illustrated. In particular, the segmented target assembly 102 includes a respective plurality of target segments 111 and 112, each of the respective plurality of target segments 111 and 112 containing a sputtering target material such as, but not limited to, aluminum and/or scandium. The magnetron system 100 further includes an internal assembly 106 underneath the segmented target assembly 102 which includes a plurality of electrical contacts 132 (FIG. 6A) and 133 (FIG. 6B) configured to contact and deliver charge individually to each target segment 111 and 112 such that each target segment 111 and 112 is negatively charged. The extent of negative charge on each target segment (111 and 112) can be independently controlled. In this manner, a sputter rate of each individual target segment 111 and 112 is modulated for film uniformity and for maintaining an ideal doping ratio between one or more sputtering materials such as scandium and/or aluminum. The internal assembly 106 further includes a magnet assembly 103 configured to induce a magnetic field to confine negatively charged electrons to a surface of the plurality of sputter target segments 111 and 112, thus maintaining film uniformity by controlling the attraction of positively charged gas ions from a plasma to the negatively charged segmented target assembly 102. Mirroring a concentric configuration of the segmented target assembly 102, the magnet assembly 103 includes an outer magnet assembly 120A and an inner magnet assembly 120B (FIG. 5). The target segments 111 and 112 can be in different planes as shown in FIG. 5. The planes of target segments 111 and 112 can be parallel. The target segments 111 and 112 can be concentric about a shared central axis.

For any embodiment, the target segments 111 and 112 can be centered on different (offset) central axes (that is the center of target segment 111 is offset from the central axis of target segment 112). Offsetting the target segment central axes from one another can be used to improve film deposition uniformity on the wafer surface. In this configuration the outer target segment 111 surrounds the inner target segment 112, but is not concentric.

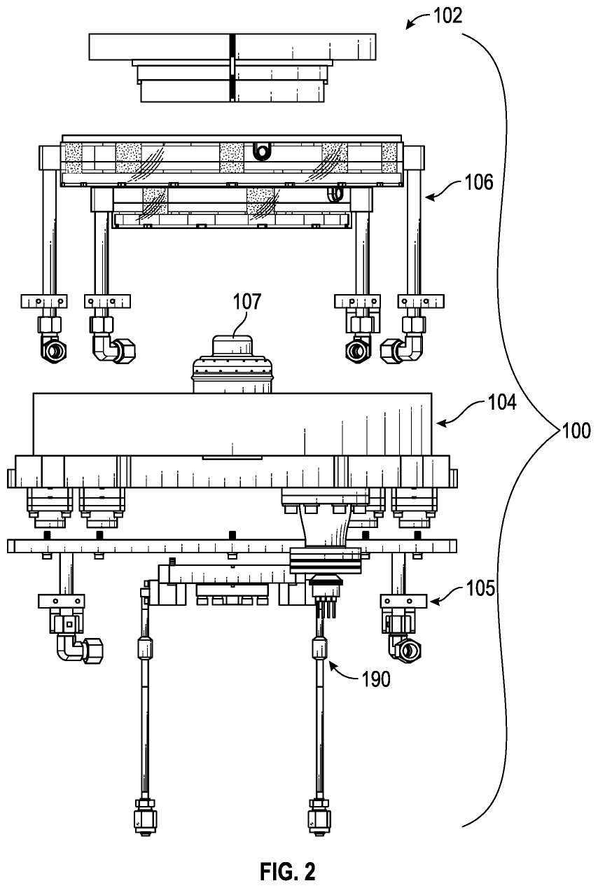

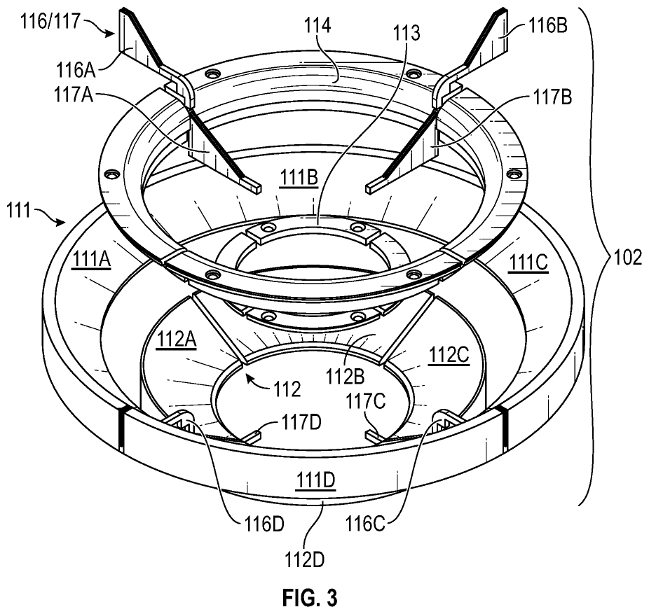

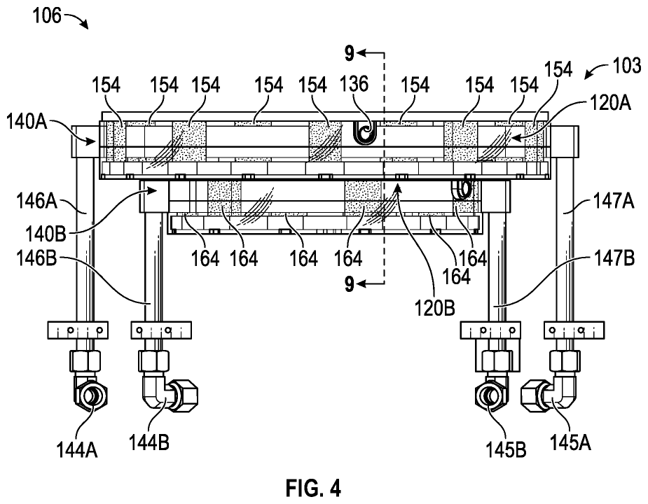

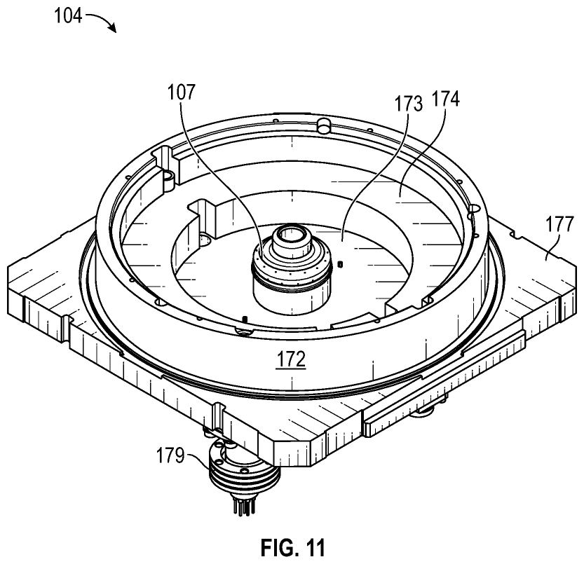

Referring to FIGS. 2 and 3, the magnetron system 100 further includes a baseplate assembly 104 having a housing portion 172 (FIG. 11) which encapsulates the internal assembly 106 and the segmented target assembly 102. The baseplate assembly 104 features a gas tower 107 for introducing a gas into the batch process chamber such that charged plasma particles can be extracted from the gas and used in the sputtering process. The gas tower 107 is connected to an external gas source (not shown) underneath the baseplate assembly 104 through a gas assembly 190. The baseplate assembly 104 further includes a power feedthrough 171 (FIG. 11) for delivering charge from an external power source (not shown) to the plurality of electrical contacts 132 (FIG. 6A) and 133 (FIG. 6B). As shown in FIG. 4, the internal assembly 106 of the magnetron system 100 further includes a water jacket assembly 140 and a cooling plate assembly 105 for cooling various parts of the magnetron system 100.

In some embodiments, an external controller (not shown) modulates power delivery to each individual target segment 111 and 112 of the segmented target assembly 102 via the plurality of electrical contacts 132 (FIG. 6A) and 133 (FIG. 6B). In this manner, sputtering rates of each individual target segment 111 and 112 of the segmented target assembly 102 can be modulated by careful control of power in the form of negative charge which is applied to each individual target segment 111 and 112 by a respective electrical contact 132 (FIG. 6A) and 133 (FIG. 6B).

In one method of depositing a film from the segmented target assembly 102 onto the wafer surface using the magnetron system 100, the wafer surface is lowered “facedown” above the segmented target assembly 102 within a batch processing chamber (not shown). Power is applied in the form of negative charge to the segmented target assembly 102 by the electrical contacts 132 and 133 and an inert gas (e.g., Ar) is then introduced into the batch processing chamber via the gas tower 107 of the magnetron system 100. The climate within the batch processing chamber is controlled such that a portion of the inert gas is separated into positively charged ions and negatively charged electrons, thereby creating a plasma. The positively charged ions are accelerated into the segmented target assembly 102 by the negatively charged electrons accumulating at a surface of the negatively charged segmented target assembly 102. The positively charged ions are accelerated and strike each negatively charged target segments 111 and 112 of the segmented target assembly 102 with enough force to dislodge and eject microscopic molecules of material from the target segments 111 and 112. A portion of such molecules of material then condense onto the wafer surface. The magnetic field generated by the magnet assembly 103 of the internal assembly 106 aids in this process by confining negatively charged electrons at the surface of the target assembly 102. The confined negatively charged electrons attract positively charged ions from the plasma to the surface of the target assembly 102, which then dislodge molecules of target material. In some embodiments, the magnetic field is tuned such that the negatively charged electrons are optimally arranged on the target assembly 102 for uniform deposition of molecules from the target assembly 102 onto the wafer. A reactive gas (e.g., nitrogen) can be added to the gas mixture to change the composition of the deposited film. (e.g., sputtering an aluminum and scandium containing target in an nitrogen containing gas mixture can yield AlScN films).

At least one target segment is comprised of 2 or more target tiles (e.g., target segment 111 contains target tiles 111A, 111B, 111C and 111D in FIG. 3). A target tile can be composed of a single element (e.g., Al or Sc). More than one target segment can be comprised of 2 or more target tiles. All target segments can b comprised of 2 or more target tiles. An individual target tile can be composed of two or more elements (e.g., an alloy such as aluminum-scandium (Sc_{0.2}Al_{0.8})).

In embodiments where at least 2 target segments contain target tiles, at least 2 tiles are in different planes. In one embodiment, the different planes are parallel to each other.

In particular, each target segments 111 and 112 of the segmented target assembly 102 can be made from either a first material or a second material such that individual sputter target tiles 111A, 111C, 112A, and 112C include the first material, and individual sputter target tiles 111B, 111D, 112B, and 112D include the second material. In some embodiments, the first material is aluminum and the second material is scandium to collectively deposit an aluminum scandium nitride (AlScN) film onto the surface of the wafer. It should be noted that scandium and aluminum sputter at different rates, and as sputtering occurs over time, the target segments 111 and 112 themselves can erode and may not sputter equally. This can cause unwanted variations in film uniformity on the wafer surface in terms of thickness and material composition. To remedy this, the magnetron system 100 delivers power in the form of negative charge individually to each sputter target segment 111 and 112 via a respective electrical contact 132 (FIG. 6A) and 133 (FIG. 6B) to modulate the sputter rate for each individual sputter target segment 111 and 112, thus allowing the magnetron system 100 to compensate for variations in material availability and sputter rate and provide a more uniform film with a precisely controlled doping ratio.

In some embodiments, a target assembly can be comprised of target tiles comprised of two different compositions. A target assembly can be comprised of tiles of more than two different compositions. A target assembly can be comprised of tiles, each with a different composition.

The previous examples discuss target tiles of a single composition. In any embodiment, at least one target tile is a composite target tile. A composite target tile is a target tile that consists of domains of more than one composition (e.g., a target tile can be two materials held together for form a single target tile). For example an individual target tile can consist of an Al sub-tile held to a Sc sub-tile to form a composite AlSc tile. A composite target tile contains more than one composition domain. A domain in a composite tile can be a pure element (e.g., Sc or Al). A domain in a composite target tile can be an alloy (e.g., a target tile with an Al domain and an AlSc domain). The size (e.g., volume) of two or more domains in a composite target tile can be the same. In a preferred embodiment, a composite target tile consists of domains such that each domain is a pure material (e.g., Sc or Al).

The segmented target assembly 102 is shown in FIG. 3. As discussed above, the segmented target assembly 102 features the plurality of target segments 111 and 112. In some embodiments, the plurality of target segments 111 and 112 collectively can form two respective concentric groupings: an outer concentric target segment 111 and an inner concentric target segment 112. As shown, in some embodiments the outer concentric target segment 111 includes target tiles 111A-111D and the inner concentric target segment 112 includes target tiles 112A-1120. It should be noted that while the embodiment of FIG. 3 includes eight target tiles contained in two target segments 111 and 112, other contemplated embodiments of the segmented target assembly 102 may include more than or less than two target segments 111 and 112 to provide increased granularity in controlling the magnetic field induced within the batch process chamber.

The example in FIG. 3 shows four (4) target tiles within each target segment (target tiles 111A, 111B, 111C and 111D within target segment 111 and target tiles 112A, 112B, 112C, and 112D within target segement 112). In all embodiments, a target segment can contain one or more tiles. In all embodiments all target segments can contain the same number of tiles.

Target segments can contain different number of tiles. In one embodiment, at least one target segment (a first target segment) is composed of a single tile (e.g., the first target segment has a homogeneous composition). In this configuration the composition of a second target segment is different from the first target segment. The second target segment consists of at least 2 tiles. At least two tiles in the second target segment have different compositions. An example of this embodiment would be where a first target segment is comprised of pure Al, and a second target segment consists of two tiles—one tile of pure Al and a second tile of pure Sc.

FIG. 3 shows and example of a sputter target configuration that contains the same number of target tiles (111A-D and 112A-D) in the outer (111) and inner (112) target segments. Furthermore, FIG. 3 shows the gaps between target tiles align between the inner and outer target segments.

In some embodiments of the magnetron system 100, target tiles 111A and 111C of the outer target segment 111 may include the first material such as aluminum (e.g., target tiles 111A and 111C are pure Al), and target tiles 1118 and 111D of the outer target segment 111 may include the second material such as scandium (e.g., target tiles 111B and 111D are pure Sc). Target tiles 111A-111D made of different materials may be arranged in an alternating manner such that target tiles 111A and 111C made of the first material are juxtapositioned between target tiles 111B and 111D made of the second material as specifically shown in FIG. 3. For deposition of a non-doped film, such as aluminum nitride (AlN), all four target tiles 111A-D may be composed of a singular material such as aluminum.

FIG. 3 shows the gaps between target files (111A-D) in the outer target segment (111) coinciding with the gaps between target tiles (112A-D) in the inner target segment (112). In some embodiments the gap between at least two target tiles in the one target segement (e.g., outer target segment 111) coincides with a target tile (e.g., of an inner target tile from a different target segment (e.g., a target tile (112A-D) from inner target segment 112 in this example). In other words at least one gap between two adjacent tiles in an outer target segment (111) does not overlap a gap between adjacent tiles of the inner target segment (112).

In some embodiments, the inner target segment 112, the target tiles 112A and 112C may include the first material such as aluminum, and target tiles 112B and 112D may include the second material such as scandium. Target tiles 112A-112D may be arranged in an alternating sequence such that target tiles 112A and 112C made of the first material are juxtapositioned between target tiles 112B and 112D made of the second material, respectively, as shown in FIG. 3. For deposition of a non-doped film such as aluminum nitride (AlN), all four target tiles 112A-D may include a singular element such as aluminum, in some embodiments (e.g., target tile composition alternates tile-to-tile within a target segment).

In some embodiments, the target tiles between the inner and outer target segments can be configured such that at least one target tile of a first composition is always adjacent to a target tile of a second composition (e.g., in FIG. 3 target tiles 111A, 111C, 112B and 112D are comprised of a first composition and target tiles 111B, 111D, 112A, and 112C are comprised of a second composition) (e.g., target tile composition alternates between inner and outer target segments).

It is important to note that each target segment 111 and 112 should be electrically isolated to allow for individual modulation of the sputtering rate. This is achieved by way of an annular target shield 114, shown in FIG. 3, which separates the outer target segment 111 from the inner target segment 112 to electrically isolate the outer target segment 111 from the inner target segment 112. In this configuration, the power applied to target segment 111 can be adjusted independently the power applied to target segment 112. The sputter rate of the material of a target is affected by the applied power. Therefore, the rate of material sputtered from different target segments can be independently adjusted by adjusting the power applied to the target segment. In the case where the target segments have similar overall compositions, this power adjustment can be used to adjust the uniformity of the deposited layer. In the case where the overall composition of target segement 111 is different from target segement 112, the composition of the deposited film can also be adjusted by adjusting the power levels applied to the different target segments.(e.g., power can be adjusted independently between the inner and outer target segments).

The electrical isolation facilitated by the annular target shield 114 can be extended to allow power to be separately applied to target tiles 111A-D of the outer target segment 111 through electrical contacts 132A-D (FIG. 6A) and target tiles 112A-D of the inner target segment 112 through electrical contacts 133A-D (FIG. 6B). In this configuration, the magnetron system 100 further includes a plurality of spacers 116 and 117 to electrically isolate at least one target tile within target segment 111 and/or at least one target tile within target segment 112 from each other. All target tiles in at least one tile segment can be electrically isolated from one another. All target tiles in all target segments can be electically isolated from one another. FIG. 3 shows the target tiles 112A-D of the outer target segment 111 are each separated by outer spacers 116A-D. Similarly, FIG. 3 shows the target tiles 112A-D of the inner target segment 112 are each separated by inner spacers 117A-D. In some embodiments, spacers 116 and 117 are of a one-piece construction (i.e., outer spacer 116A and inner spacer 117A are one piece, outer spacer 116B and inner spacer 117B are one piece, etc.). In some embodiments, outer spacers 116 and inner spacers 117 are a non-conducting material with insulating properties, such as, but not limited to, ceramic or another insulating material. In other embodiments, the target segments 111 and 112 are isolated from one another by a gap. Further referring to FIG. 3, an annular retainer ring 113 is positioned interior to the inner target segment 112 for securing the inner target segment 112 within the magnetron system 100.

It is common in the art to bond (e.g., adhesively attach) the sputter target (e.g., target segment 111) to the internal assembly (106). Through the use of an annular retaining ring (e.g., annular ring 113), a sputter target segment (e.g., target segment 112) can be held in intimate contact with the internal assembly (106) without the use of adhesives (e.g., solder) or a bonding process (e.g., anodic bonding, etc.). This makes it easier to change the configuration of the target segments (e.g., the number and /or composition of target tiles within a target segment) without the need to first debond the targets from the internal assembly (106).

Referring to FIGS. 3 and 6, in one aspect, negative charge is applied to each individual target tiles 111A-D and 112A-D through each respective electrical contact 132A-D (FIG. 6A) and 133A-D (FIG. 6B) of the magnetron system 100. Each electrical contact 132 (FIG. 6A) and 133 (FIG. 6B) physically contacts a respective target segment 111 and 112 to deliver power in the form of charge to each respective target segment 111 and 112. In particular, for the outer target segment 111, electrical contact 132A contacts and delivers power to target tile 111A, electrical contact 132B contacts and delivers power to target tile 111B, electrical contact 132C contacts and delivers power to target tile 111C, and electrical contact 132D contacts and delivers power to target tile 111D. Similarly, for the inner target segment 112, electrical contact 133A contacts and delivers power to target tile 112A, electrical contact 133B contacts and delivers power to target tile 112B, electrical contact 133C contacts and delivers power to target tile 112C, and electrical contact 133D contacts and delivers power to target tile 112D. It should be noted that while the embodiment of FIGS. 6A and 6B includes eight electrical contacts 132 and 133, other contemplated embodiments may include more than or less than eight electrical contacts 132 and 133 corresponding with any additional tiles and/or target segments (FIG. 3) to provide increased granularity in controlling the magnetic field induced within the batch process chamber (e.g., this allows power to be delivered independently to at least two different target segments and/or target tiles).

Referring to FIGS. 4, and 5, the internal assembly 106 is shown including the magnet assembly 103 which is configured to induce a magnetic field to confine negatively charged electrons to sputter target segments 111 and 112 (FIG. 3) of the segmented target assembly 102 while maintaining film uniformity by controlling attraction of positively charged gas ions to the negatively charged segmented target assembly 102. The magnet assembly 103 includes an outer magnet assembly 120A and an inner magnet assembly 120B, respectively corresponding to the outer target segment 111 and the inner target segment 112. The magnet assembly 103 includes the plurality of electrical contacts 132 (FIG. 6A) and 133 (FIG. 6B) in electrical communication with an external power source (not shown), with each electrical contact 132 and 133 applying power to a respective target segment 111 and 112, as discussed above. As specifically shown in FIG. 5, the outer magnet assembly 120A is operable to receive an outer water jacket 140A that forms a part of the water jacket assembly 140 for cooling the outer magnet assembly 120A and the plurality of electrical contacts 132 (FIG. 6A). Similarly, the inner magnet assembly 120B is operable to receive an inner water jacket 140B that also forms a part of the water jacket assembly 140 for cooling the inner magnet assembly 120B and plurality of electrical contacts 133 (FIG. 6B). As shown in FIGS. 4 and 5, the inner water jacket 140B is situated underneath the outer water jacket 140A. The outer water jacket 140A and inner water jacket 140B may each include a respective inlet tube 146A and 146B and a respective outlet tube 147A and 147B for piping coolant in and out of the outer water jacket 140A and inner water jacket 140B.

Referring directly to FIG. 6A, each electrical contact 132 of the plurality of electrical contacts 132 is seated within the outer magnet assembly 120A of the magnet assembly 103 via a power block 134. Similarly, as shown in FIG. 6B, each electrical contact 133 of the plurality of electrical contacts 133 is seated within the inner magnet assembly 120B of the magnet assembly 103 via a respective power block 135. Specifically, each power block 134 (FIG. 6A) receives a respective electrical contact 132 (FIG. 6A) and each power block 135 (FIG. 6B) receives a respective electrical contact 133 (FIG. 6B). For the outer magnet assembly 120A associated with the outer target segment 111 (FIG. 3), power block 134A receives electrical contact 132A; power block 134B receives electrical contact 132B; power block 134C receives electrical contact 132C, and power block 134D receives electrical contact 132D. Similarly, for the inner magnet assembly 120B associated with the inner target segment 112 (FIG. 3), power block 135A receives electrical contact 133A; power block 135B receives electrical contact 133B; power block 135C receives electrical contact 133C, and power block 135D receives electrical contact 133D. It should be noted that while the embodiment of FIGS. 6A and 6B includes eight power blocks 134 and 135, other contemplated embodiments may include more than or less than eight power blocks 134 and 135 corresponding with any additional electrical contacts 132 and 133 to provide increased granularity in controlling the magnetic field induced within the batch process chamber.

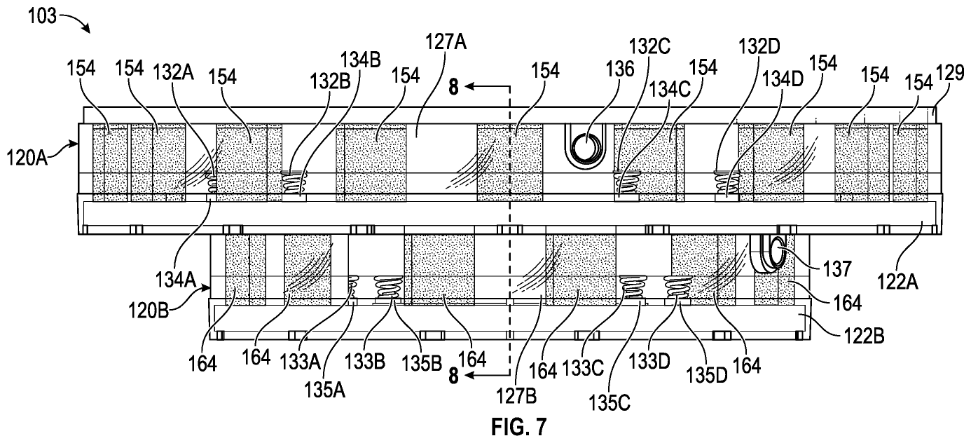

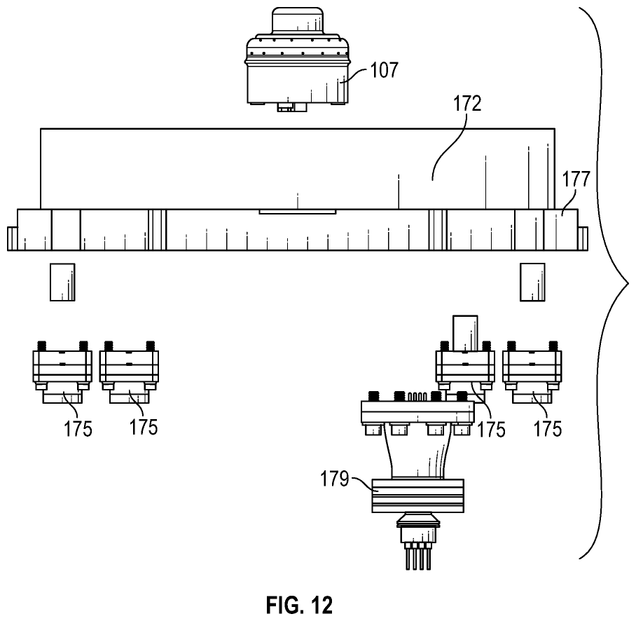

Referring to FIG. 7, the outer magnet assembly 120A and inner magnet assembly 120B of the magnet assembly 103 each define a respective outer power aperture 136 and an inner power aperture 137 which each provide a respective portal for wires (not shown) or other conductive material to electrically couple each electrical contact 132 and 133 with a power feedthrough 179 (FIG. 12) of the baseplate assembly 104 (FIG. 12). In particular, conductive material (not shown) can be passed through the outer power aperture 136 and coupled with each of the plurality of power blocks 134A-D of the outer magnet assembly 120A to provide power to each electrical contact 132A-D. Similarly, conductive material (not shown) can be passed through the inner power aperture 137 and coupled with each of the plurality of power blocks 135A-135D of the inner magnet assembly 120B to provide power to each respective electrical contact 133A-D. Referring to FIG. 12, the power feedthrough 179 is engaged with an underside (not shown) of the baseplate assembly 104 and provides a conduit for power to be routed to each respective power block 135/136 from an external power source (not shown). In some embodiments, the external power source and/or power feedthrough 179 are in electrical communication with a controller (not shown) which is operable for determining and/or controlling an optimal power output to be delivered to each respective target segment 111 and 112 (FIG. 3) through each respective electrical contact 132 and 133.

Referring to FIGS. 6-9, the outer and inner magnet assemblies 120A and 120B of the magnet assembly 103 are respectively shown in FIGS. 6A and 6B. As discussed above, the outer and inner magnet assemblies 120A and 120B induce a magnetic field within the batch processing chamber to confine negatively charged electrons to the segmented target assembly 102 in order to control attraction of positively charged gas ions to the segmented target assembly 102 and thus controlling the sputtering process. The diameter of the inner magnet assembly 120B is less than that of the outer magnet assembly 120A, as shown in FIG. 7. In some embodiments, the diameter of the outer magnet assembly 120A is 11 inches and the diameter of the inner magnet assembly 120B is 7 inches, however, embodiments of the magnet assembly 103 are not limited to these diameters. The outer magnet assembly 120A, shown specifically in FIG. 6A, includes a plurality of magnet pairs 154 arranged concentrically around a central axis Z. Similarly, the inner magnet assembly 120B, shown specifically in FIG. 6B, includes a plurality of magnet pairs 164 arranged concentrically around a central axis Z.

Referring to FIG. 6A, each magnet pair 154 of the outer magnet assembly 120A includes a respective vertically oriented magnet 154A aligned with the central axis Z and a respective horizontally oriented magnet 154B oriented perpendicular to the respective vertically oriented magnet 154A aligned with central axis Z. Similarly, referring to FIG. 6B, each magnet pair 164 of the inner magnet assembly 120B includes a respective vertically oriented magnet 164A aligned with the central axis Z and a respective horizontally oriented magnet 164B oriented perpendicular to the respective vertically oriented magnet 164A aligned with central axis Z. As shown in FIGS. 5, 6A and 6B, the outer and inner magnet assemblies 120A and 120B include respective water jacket notches 128A and 128B for receiving each respective outer and inner water jacket assembly 140A and 140B. Each magnet 154A, 154B, 164A and 164B is a permanent magnet.

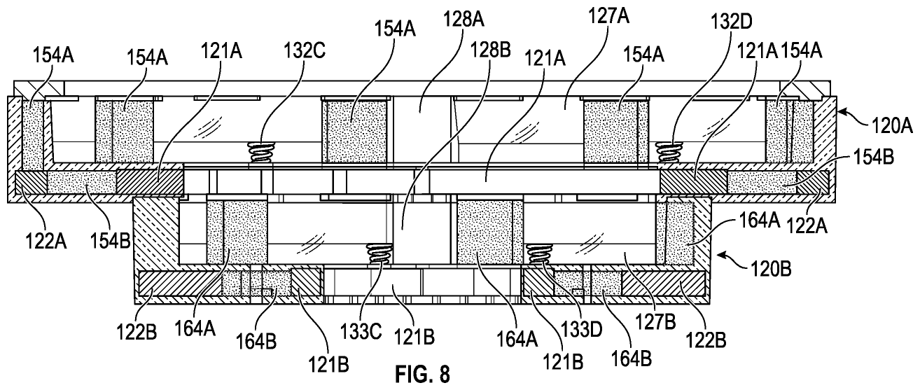

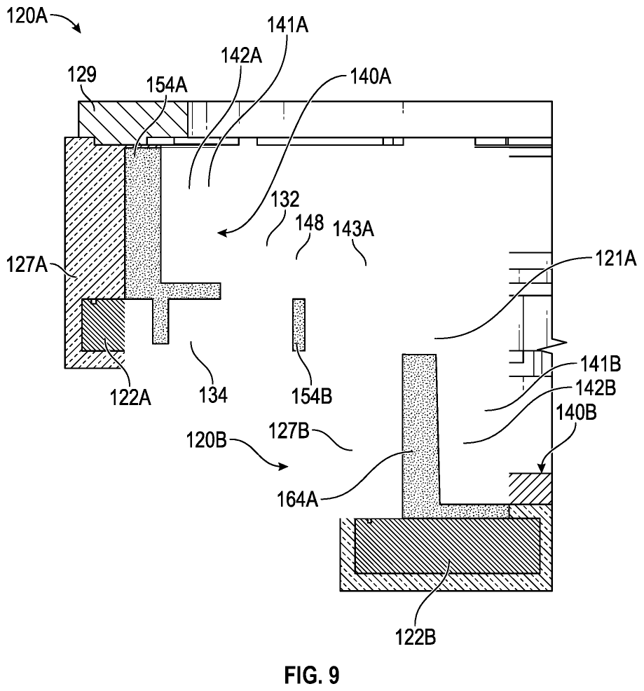

In some embodiments shown in FIG. 8, the magnet assembly 120 defines a magnetic circuit which is completed by connection between components of the outer magnet assembly 120A and the inner magnetic assembly 120B. In some embodiments shown in FIGS. 6A and 6B, outer magnet assembly 120A (FIG. 6A) includes a first outer pole piece 122A located underneath each vertically oriented magnet 154A and positioned externally relative to each horizontally oriented magnet 154B for structural support and for completion of a magnetic connection between each vertically oriented magnet 154A and each horizontally oriented magnet 154B. Further, the outer magnet assembly 120A includes a first inner pole piece 121A located internal to each horizontally oriented magnet 154B for additional structural support and for completion of a magnetic connection between each horizontally oriented magnet 154B of the outer magnet assembly 120A and each vertically oriented magnet 164A of the inner magnet assembly 120B. Similarly, the inner magnet assembly 120B (FIG. 6B) includes a second outer pole piece 122B located underneath each vertically oriented magnet 164A and positioned externally relative to each horizontally oriented magnet 164B for completion of a magnetic connection between each vertically oriented magnet 164A and each horizontally oriented magnet 164B, as well as a second inner pole piece 121B located internal to each horizontally oriented magnet 164B for structural support and completion of the magnetic connection. In some embodiments, as shown in FIGS. 8 and 9, an upper pole piece 129 is included above the outer magnet assembly 120A for completion of the magnetic circuit. In some embodiments, each pole piece including the upper pole piece 129, first and second outer pole pieces 122A and 122B, and first and second inner pole pieces 121A and 121B includes a plurality of self-alignment indentations (not shown) for receipt and alignment of each magnet 154A, 154B, 164A and 164B. Each pole piece 129, 122A, 122B, 121A and 121B forces each magnet 154A, 154B, 164A and 164B to magnetically align with the pole pieces 129, 122A, 122B, 121A and 121B, improving magnetic uniformity and magnetic flux through the permanent magnets 154A, 154B, 164A and 164B.

For formation of the outer magnet assembly 120A, each magnet pair 154 of the outer magnet assembly 120A is encased in a nonconductive resin 127A, as shown in FIG. 6A, to provide for structural support as well as to prevent the magnet pairs 154 from shifting. Similarly, for formation of the inner magnet assembly 120B, each magnet pair 164 of the inner magnet assembly 120B is encased in a nonconductive resin 127B, as shown in FIG. 6B, to provide for structural support as well as to prevent the magnet pairs 164 from shifting. Further, in some embodiments, each pole piece 129, 122A, 122B, 121A and 121B are encapsulated within the nonconductive resin 127A and 127B.

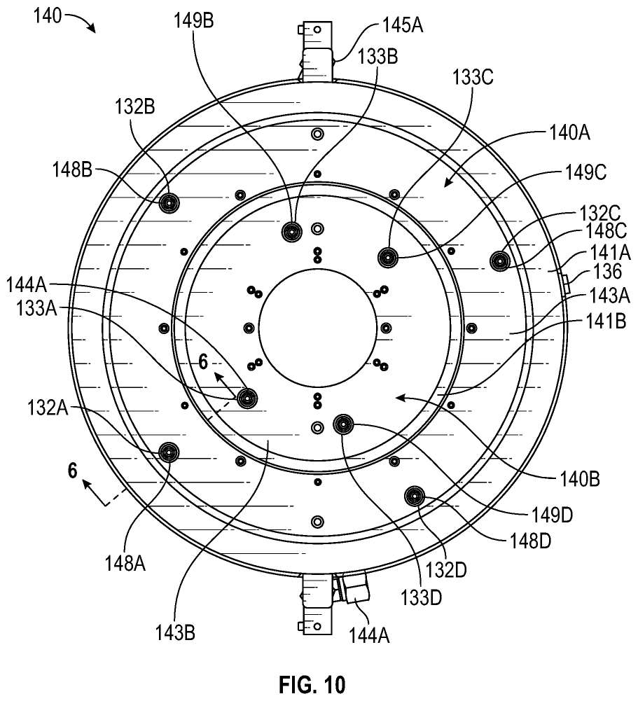

Referring to FIGS. 4, 5, 9 and 10, the water jacket assembly 140 includes an outer water jacket 140A for cooling the outer magnet assembly 120A and an inner water jacket 140B for cooling the inner magnet resin pack 120B. As shown in FIGS. 9 and 10, the outer water jacket 140A defines an outer water jacket wall 141A formed circumferentially around an outer water jacket plane 143A. The outer water jacket wall 141A includes an outer channel 142A in fluid flow communication with an inlet tube 147A (FIG. 5) and an outlet tube 146A (FIG. 5) with the inlet tube 147A and the outlet tube 146A respectively terminating in an inlet port 145A (FIG. 4) and an outlet port 144A (FIG. 4). The outer channel 142A follows the circumference of the outer water jacket wall 141A, allowing water, or another heat transfer fluid suitable for high performance liquid cooling applications, to envelop the outer magnet assembly 120A and absorb heat. The outer water jacket plane 143A rests atop the plurality of horizontally oriented magnets 154B of the outer magnet assembly 120A. In some embodiments, as shown in FIGS. 9 and 10, the outer water jacket plane 143A includes a plurality of contact apertures 148A-148D such that the plurality of electrical contacts 132A-132D can extend from each power block 134A-1340 of the outer magnet assembly 120A through the outer water jacket plane 143A via each respective contact aperture 148A-148D and contact each respective segmented target 111 of the segmented target assembly 102. Referring to FIG. 5, an outer backplate 138 is engaged with the outer water jacket 140A for improved stability.

Similarly, the inner water jacket 140B defines an inner water jacket wall 141B circumferentially formed around an inner water jacket plane 143B. The inner water jacket wall 141B includes an inner channel 142B in fluid flow communication with an inlet tube 147B (FIG. 5) and an outlet tube 146B (FIG. 5) with the inlet tube 147B and the outlet tube 146B respectively terminating in an inlet port 145B (FIG. 4) and an outlet port 144B (FIG. 4). The inner channel 142B follows the circumference of the inner water jacket wall 141B, allowing water, or another heat transfer fluid suitable for high performance liquid cooling applications, to envelop the inner magnet assembly 120B and absorb heat. The water jacket plane 143B rests atop the plurality of horizontally oriented magnets 164B of the inner magnet assembly 120B. In some embodiments, components of the water jacket 140 such as the outer jacket plane 143A and the inner water jacket plane 143B are coated in ceramic or another material which exhibits low electrical and/or thermal conductivity.

In some embodiments, as shown in FIGS. 9 and 10, the water jacket plane 143B includes a plurality of contact apertures 149 such that the plurality of electrical contacts 133 can extend from each power block 135 of the inner magnet resin pack 120B through the water jacket plane 143B and contact each segmented target 112 of the segmented target assembly 102. Referring to FIG. 5, an inner backplate 139 is engaged with the outer water jacket 140A for improved stability. It should be noted that while the embodiment of FIG. 10 includes eight contact apertures 148 and 149, other contemplated embodiments may include more than or less than eight contact apertures 148 and 149 corresponding with any additional electrical contacts 132 (FIG. 6A) and 133 (FIG. 6B) to provide increased granularity in controlling the magnetic field induced within the batch process chamber.

Referring to FIGS. 2, 11, and 12, the baseplate assembly 104 provides structural support for the water jacket assembly 140, the magnet assembly 103, and the segmented target assembly 102. The baseplate assembly 104 also facilitates electrical communication between an external power source (not shown) and the plurality of electrical contacts 132/133 via power feedthrough 171 as well as providing structural support for the inlet tubes 147A/147B and outlet tubes 146A/146B of the water jacket assembly 140 using a plurality of water tube feedthroughs 175.

Referring directly to FIGS. 11 and 12, the baseplate assembly 104 includes the housing portion 172 extending upward from a planar portion 177. The housing portion 172 includes an outer recess 174 configured to receive the outer magnet 120A and an inner recess 173 configured to receive the inner magnet assembly 120B. As shown, the baseplate assembly 104 further includes a plurality of water tube feedthroughs 175 for insertion of each of the inlet tubes 147A and 147B (FIG. 3) and outlet tubes 146A and 146B (FIG. 3) of the water jacket assembly 140. The baseplate assembly 104 further includes the gas tower 107 in fluid flow communication with an external gas source (not shown) for introduction of the process gas (e.g., inert gas such as Ar, and/or reactive gases such as N₂, etc.) into the batch processing chamber. The gas tower 107 is located in the center of the outer recess 174 and inner recess 173 of the housing portion 172 and extends upward through the internal assembly 106 and segmented target assembly 102, as shown in FIGS. 1 and 2.

Referring to FIG. 2, a cooling plate 105 is further included and engaged with the baseplate 104 of the magnetron system 100 for additional cooling of the magnetron assembly 100.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

What is claimed is:

1. A magnetron system, comprising:
a baseplate assembly defining a housing portion and a power feedthrough;
a segmented target assembly having an inner target segment disposed within the housing portion, the inner target segment having a plurality of target tiles;
a plurality of electrical contacts in electrical communication with the power feedthrough, wherein each electrical contact of the plurality of electrical contacts electrically contacts a respective target tile of the plurality of target tiles such that power is delivered from each electrical contact of the plurality of electrical contacts to each respective target tile of the plurality of target tiles; and
a magnet assembly disposed within the housing portion.

2. The system of claim 1, wherein the segmented target assembly further comprising an outer target segment having a plurality of target tiles wherein the outer target segment surrounds the inner target segment.

3. The system of claim 2, wherein the magnet assembly further comprising:
an outer magnet assembly comprising a first grouping of the plurality of magnet pairs; and
an inner magnet assembly comprising a second grouping of the plurality of magnet pairs;
wherein the outer magnet assembly surrounds the inner magnet assembly.

4. The system of claim 3, further comprising:
a water jacket assembly, wherein the water jacket assembly comprises:
an outer water jacket disposed within an outer magnet assembly of the magnet assembly; and
an inner water jacket disposed within an inner magnet assembly of the magnet assembly.

5. The system of claim 4, wherein the inner target segment is in a concentric configuration, the outer target segment is in a concentric configuration, the inner magnet assembly is in a concentric configuration, the outer magnet assembly is in a concentric configuration, the inner water jacket is in a concentric configuration, and the outer water jacket is in a concentric configuration.

6. The system of claim 1, wherein the baseplate assembly further comprising:
a gas tower in fluid flow communication with a gas assembly, the gas tower being operable for introducing a gas into the system.

7. The system of claim 3, wherein each magnet pair further comprising a vertical magnet and a horizontal magnet, each vertical magnet being aligned with an axis Z and each horizontal magnet being aligned perpendicular to each vertical magnet.

8. The system of claim 1, further comprising a first subset of the plurality of target tiles having a first material; and a second subset of the plurality of target tiles having a second material.

9. The system of claim 8, wherein the plurality of target tiles are arranged in an alternating order such that a target tile of the plurality of target tiles having the first material is juxtapositioned between two target tiles of the plurality of target tiles having the second material, and a target tile of the plurality of target tiles having the second material is juxtapositioned between two target tiles of the plurality of target tiles having the first material.

10. The system of claim 8, wherein the first material is aluminum.

11. The system of claim 10, wherein the second material is scandium.

12. The system of claim 1, wherein the plurality of target tiles are electrically isolated from one another.

13. The system of claim 12, wherein the outer target segment and the inner target segment are electrically isolated from one another by an annular target shield.

14. The system of claim 12, wherein the outer target segment and the inner target segment are electrically isolated from one another by a plurality of spacers.

15. The system of claim 1, wherein the magnet assembly being positioned inferior to the segmented target assembly, the magnet assembly having a plurality of magnet pairs, each magnet pair being positioned annularly around a central axis Z.

16. The system of claim 15, wherein the magnet assembly further comprising a plurality of pole pieces and wherein each magnet pair contacts at least two pole pieces of the plurality of pole pieces.

17. The system of claim 16, wherein a diameter of the inner magnet assembly is less than a diameter of the outer magnet assembly.

18. A magnetron system, comprising:
a baseplate assembly defining a housing portion and a power feedthrough;
a segmented target assembly disposed within the housing portion, the segmented target assembly having an inner target segment having a plurality of target tiles and an outer target segment having a plurality of target tiles, wherein a first subset of the plurality of target tiles having a first material and wherein a second subset of the plurality of target tiles having a second material, wherein the plurality of target tiles are arranged in an alternating order such that a target tile of the plurality of target tiles having the first material is juxtapositioned between two target tiles of the plurality of target tiles having the second material, and a target tile of the plurality of target tiles having the second material is juxtapositioned between two target tiles of the plurality of target tiles having the first material; and
a magnet assembly disposed within the housing portion.

19. The system of claim 18, wherein each target tile of the plurality of target tiles is electrically isolated from one another.

20. The system of claim 18, further comprising a plurality of electrical contacts in electrical communication with the power feedthrough, wherein each electrical contact of the plurality of electrical contacts electrically contacts a respective target tile of the plurality of target tiles such that power is delivered from each electrical contact of the plurality of electrical contacts to each respective target tile of the plurality of target tiles.
